(19) United States
(12) Patent Application Publication
(10) Pub. No.: US 2024/0364073 A1
(43) Pub. Date: Oct. 31, 2024

(54) METHOD FOR PRODUCING A MULTIPLICITY OF SEMICONDUCTOR LASER CHIPS, AND SEMICONDUCTOR LASER CHIP

(71) Applicant: ams-OSRAM International GmbH, Regensburg (DE)

(72) Inventors: Norwin VON MALM, Nittendorf (DE); Martin Rudolf BEHRINGER, Regensburg (DE)

(73) Assignee: ams-OSRAM International GmbH, Regensburg (DE)

(21) Appl. No.: 18/682,606

(22) PCT Filed: Aug. 4, 2022
(86) PCT No.: PCT/EP2022/071947

§ 371 Date: Feb. 9, 2024

(30) Foreign Application Priority Data
Aug. 12, 2021 (DE) 10 2021 121 026.7

(51) Int. Cl. H01S 5/02; H01S 5/02326; H01S 5/028; H01S 5/185

(52) U.S. Cl. CPC H01S 5/0201; H01S 5/02326; H01S 5/0282; H01S 5/185; H01S 2301/176

(57) ABSTRACT

A method for producing a multiplicity of semiconductor laser chips, the method including growing a semiconductor layer having an active region, forming a multiplicity of laser chip regions, each laser chip region having a part of the active region, a part of the semiconductor layer, a first mirror and a second mirror, applying a sacrificial layer to the laser chip regions, shaping at least one support region per laser chip region within the sacrificial layer, applying an auxiliary carrier to the sacrificial layer, singulating the laser chip regions into semiconductor laser chips on the auxiliary carrier, each semiconductor laser chip having a first region of the semiconductor layer and a second region of the semiconductor layer, the first region and the second region having mutually different extents parallel to the main plane of extent of the semiconductor layer, and the first mirror and the second mirror adjoining the second region, removing the sacrificial layer, and simultaneously transferring at least some of the semiconductor laser chips to a carrier. A semiconductor laser chip is additionally specified.

### CROSS-REFERENCE TO RELATED APPLICATIONS

The present application is a national stage entry from International Application No. PCT/EP2022/071947, filed on Aug. 4, 2022, published as International Publication No. WO 2023/016912 A1 on Feb. 16, 2023, and claims priority to German Patent Application No. 10 2021 121 026.7, filed Aug. 12, 2021, the disclosures of all of which are hereby incorporated by reference in their entireties.

### FIELD

A method for producing a plurality of semiconductor laser chips and a semiconductor laser chip are provided.

### BACKGROUND

The manufacturing of semiconductor laser chips and their assembly are often complex and costly. So, the manufacturing often includes the formation of mirrors by scribing and breaking, coating and singulation processes and inspection. Subsequently, the assembly and the alignment are performed, which are performed separately for each semiconductor laser chip. This leads to time-consuming and expensive assembly.

A problem to be solved is to provide an efficient method for producing a plurality of semiconductor laser chips. A further problem to be solved is to provide a semiconductor laser chip that can be manufactured efficiently.

### SUMMARY

According to at least one embodiment of the method for producing a plurality of semiconductor laser chips, the method comprises a method step in which a semiconductor layer with an active region is grown. The semiconductor layer can be epitaxially grown on a growth substrate. The semiconductor layer can comprise an n-doped region and a p-doped region. The n-doped region and the p-doped region can be arranged one above the other in a growth direction of the semiconductor layer. The active region is arranged between the n-doped region and the p-doped region. The active region can be adapted to emit electromagnetic radiation during operation of a semiconductor laser chip. The active region can comprise quantum wells. The semiconductor layer is formed with a semiconductor material, such as, for example, a III-V compound semiconductor material, for example GaN. The semiconductor layer comprises a main extension plane.

According to at least one embodiment of the method, the method comprises the formation of a plurality of laser chip regions, wherein each laser chip region comprises a portion of the active region, a portion of the semiconductor layer, a first mirror and a second mirror. Each laser chip region is adapted to be singulated into a semiconductor laser chip. Each laser chip region comprises a region that represents a resonator in a semiconductor laser chip. The resonators each comprise a portion of the active region and the semiconductor layer, and a first mirror and a second mirror which bound the resonator, respectively. The resonators are spaced apart from each other. The laser chip regions are each directly adjacent to each other. Thereby, the laser chip regions are arranged adjacent to each other at nodes of a 2-dimensional grid. The laser chip regions thus form a 2-dimensional array on the growth substrate. Further, it is possible that the laser chip regions form a 2-dimensional array on a region of the semiconductor layer. This region of the semiconductor layer comprises the same extension along the growth direction of the semiconductor layer in all laser chip regions. The growth direction of the semiconductor layer runs perpendicular to the main extension plane of the semiconductor layer.

According to at least one embodiment of the method, the method comprises the deposition of a sacrificial layer on the laser chip regions. Prior to depositing the sacrificial layer, electrical contacts of the laser chip regions can be formed. Thereby, each laser chip region can comprise at least two electrical contacts. The electrical contacts can be arranged on a side of the semiconductor layer facing away from the substrate. On the electrical contacts, a metal can be applied respectively. Between the regions in which the metal is deposited, a dielectric material can be deposited. Prior to the deposition of the sacrificial layer, the dielectric material and the metal can be planarized. The sacrificial layer is deposited on the laser chip regions on a side of the semiconductor layer facing away from the substrate. The sacrificial layer completely covers the laser chip regions. The sacrificial layer is designed to be removed in an etching process.

According to at least one embodiment of the method, the method comprises forming at least one support region per laser chip region within the sacrificial layer. The support regions can each extend completely through the sacrificial layer perpendicular to the main extension plane of the semiconductor layer. The support regions can comprise a three-dimensional shape. For example, each support region comprises the shape of a cylinder or a cuboid. The support regions each comprise a material that is different from the material of the sacrificial layer. It is further possible that per laser chip region two or three support regions are arranged within the sacrificial layer.

According to at least one embodiment of the method, the method comprises the deposition of an auxiliary carrier on the sacrificial layer. The auxiliary carrier can be mechanically connected with the sacrificial layer. The auxiliary carrier is applied to the sacrificial layer on the side facing away from the semiconductor layer. The auxiliary carrier can completely cover the sacrificial layer. A connection layer can be arranged between the auxiliary carrier and the sacrificial layer. Thus, the auxiliary carrier can be attached to the sacrificial layer via the connection layer.

According to at least one embodiment of the method, the method comprises singulating the laser chip regions into semiconductor laser chips on the auxiliary carrier, wherein each semiconductor laser chip comprises a first region of the semiconductor layer and a second region of the semiconductor layer, wherein the first mirror and the second mirror are adjacent to the second region. The laser chip regions can be singulated along a direction which runs perpendicular to the main extension plane of the semiconductor layer. Thereby, the laser chip regions are singulated up to the sacrificial layer. After the singulation, each semiconductor laser chip comprises a semiconductor layer with a first region and a second region. The first region and the second region each extend parallel to the main extension plane of the semiconductor layer. For each semiconductor laser chip, the first mirror and the second mirror can be in direct contact with the second region. Thereby, the first mirror and the second mirror can be arranged on opposite sides of the second region. The first mirror and the second mirror can each extend perpendicularly or transversely to the main extension plane of the semiconductor layer. The first mirror and the second mirror can each include an angle of at least 40° and at most 50° with the main extension plane of the semiconductor layer. The semiconductor laser chips can each comprise an edge emitting laser or a horizontal cavity surface emitting laser.

According to at least one embodiment of the method, the method comprises the removal of the sacrificial layer. The sacrificial layer can be removed by etching. Since the semiconductor laser chips are arranged spaced apart from each other, recesses are arranged between the individual semiconductor laser chips. The sacrificial layer can be removed through these recesses.

According to at least one embodiment of the method, the method comprises the simultaneous transfer of at least some of the semiconductor laser chips onto a carrier. This can mean that at least two of the semiconductor laser chips are transferred onto a carrier simultaneously. It is further possible that at least three, at least five, or at least ten semiconductor laser chips are transferred onto a carrier simultaneously. Prior or during transferring to the carrier, the auxiliary carrier is removed. The carrier can be a photonic substrate or another optical system. It is further possible that the carrier is a photonic integrated circuit (PIC) or that the carrier comprises a photonic integrated circuit (PIC). It is further possible that the carrier is a temporary carrier from which the semiconductor laser chips or some of the semiconductor laser chips are mounted on a system on which they can be used.

According to at least one embodiment of the method for producing a plurality of semiconductor laser chips, the method comprises growing a semiconductor layer with an active region, forming a plurality of laser chip regions, wherein each laser chip region comprises a portion of the active region, a portion of the semiconductor layer, a first mirror and a second mirror, depositing a sacrificial layer on the laser chip regions, forming at least one support region per laser chip region within the sacrificial layer, depositing an auxiliary carrier on the sacrificial layer, singulating the laser chip regions into semiconductor laser chips on the auxiliary carrier, wherein each semiconductor laser chip comprises a first region of the semiconductor layer and a second region of the semiconductor layer, wherein the first mirror and the second mirror are adjacent to the second region, removing the sacrificial layer, and simultaneously transferring at least some of the semiconductor laser chips to a carrier.

The method described herein for producing a plurality of semiconductor laser chips is based, among other things, on the idea that a plurality of semiconductor laser chips can be produced simultaneously. Furthermore, the method enables the simultaneous, i.e. parallel, transfer of semiconductor laser chips onto a carrier. Thus, a plurality of laser chip regions is first fabricated, which are singulated into semiconductor laser chips on an auxiliary carrier. Thus, advantageously, a plurality of semiconductor laser chips can be manufactured simultaneously. The individual semiconductor laser chips are not manufactured by breaking and scribing, but the mirrors are each deposited on the second region of the semiconductor layer and then the laser chip regions are singulated. By avoiding scribing and breaking processes, the semiconductor laser chips can be manufactured more efficiently because the manufacturing of the semiconductor laser chips can be performed simultaneously for the semiconductor laser chips. Advantageously, no single chip processes are required. Thus, the semiconductor laser chips can also be produced at a low cost.

Furthermore, scribing and breaking processes usually require area reserves, which means that laser chip regions must comprise a certain distance to each other in order to enable scribing and breaking. This is not necessary in the method described herein, such that the laser chip regions can comprise smaller distances from each other. Therefore, more semiconductor laser chips can be manufactured on a given area. Thus, the manufacturing process is more efficient and cost-effective.

After the removal of the sacrificial layer, the semiconductor laser chips are each connected to the auxiliary carrier via the support regions. The support regions can be small enough to facilitate a detachment of the semiconductor laser chips from the support regions and thus from the auxiliary carrier. Thus, the detaching of the semiconductor laser chips can be performed simultaneously for some or a plurality of the semiconductor laser chips. After or during the detaching, the semiconductor laser chips can be simultaneously transferred to the carrier. Thus, it is not necessary to mount and to adjust each semiconductor laser chip separately. Instead, a parallel transfer of a plurality of semiconductor laser chips is possible. During the transfer, the relative arrangement of the semiconductor laser chips to each other can be maintained so that the semiconductor laser chips can be positioned on the carrier with a high accuracy. This means that the semiconductor laser chips can be simultaneously mounted on the carrier with a high accuracy relative to the carrier and to structures such as electrical contacts. Thus, the method enables simple and efficient mounting and alignment of the semiconductor laser chips.

According to at least one embodiment of the method, the first region and the second region comprise different extensions or extents from each other parallel to the main extension plane of the semiconductor layer. This can mean, that the first region comprises a size parallel to the main extension plane of the semiconductor layer, that is different from the size of the second region parallel to the main extension plane of the semiconductor layer. With this structure, a plurality of semiconductor laser chips can advantageously be manufactured simultaneously as described above and below.

According to at least one embodiment of the method, the transfer is performed with a stamp, which is reversibly connected to the side of at least some of the semiconductor laser chips facing away from the auxiliary carrier. Prior to connecting with the stamp, the growth substrate of the semiconductor layer can be removed. Further, it is possible that the semiconductor layer is thinned prior to the application of the stamp. The semiconductor laser chips can be planar or planarized on the side, on which the stamp is applied. The stamp can be bonded directly to the semiconductor laser chips. For example, the stamp comprises silicone. Further, it is possible that a bonding material is disposed between the stamp and the semiconductor laser chips. For transferring at least some of the semiconductor laser chips, these are simultaneously connected to the stamp on their side facing away from the auxiliary carrier. It is further possible that all semiconductor laser chips are simultaneously connected to the stamp at their side facing away from the auxiliary carrier. Subsequently, the connection of the semiconductor laser chips with the support regions is disconnected. For this, for example, the stamp can be moved parallel to the main extension plane of the semiconductor layer. Once the connections to the support regions are disconnected, the auxiliary carrier is removed. Then the semiconductor laser chips are transferred to the carrier. For this, the stamp with the semiconductor laser chips is positioned above the carrier and, subsequently, the stamp is removed. This means, the connection between the semiconductor laser chips and the stamp is disconnected. This happens when the semiconductor laser chips are already very close above the surface of the carrier or the semiconductor laser chips are already in contact with the carrier. This enables accurate positioning of the semiconductor laser chips with respect to the carrier. Thus, the semiconductor laser chips can be positioned, for example, precisely on electrical contacts of the carrier or precisely with respect to waveguides on the carrier. Thus, the semiconductor laser chips can be mounted precisely and efficiently. The transfer process with a stamp can be a μ-transfer printing process.

According to at least one embodiment of the method, the transferring comprises a laser-induced transfer, in which the connection between at least some of the semiconductor laser chips and the auxiliary carrier is released using a laser. The laser-induced transfer can be a laser-induced forward transfer. To transfer at least some of the semiconductor laser chips, the auxiliary carrier with the semiconductor laser chips is positioned close to the carrier. Then, for at least some of the semiconductor laser chips, the connection between the respective semiconductor laser chip and the at least one support region is severed. For this, a laser beam is directed to the connection between the respective semiconductor laser chip and the at least one support region. As a result, the connection between the semiconductor laser chip and the respective at least one support region is separated. This can mean that the material of the support regions is at least locally decomposed by the laser radiation. Since the auxiliary carrier with the semiconductor laser chips is already positioned very close to the carrier, the semiconductor laser chips can be positioned precisely or accurately on the carrier. This means that the semiconductor laser chips can be positioned precisely relative to the carrier, for example, to electrical contacts or waveguides on the carrier. Thus, the semiconductor laser chips can be mounted precisely and efficiently.

After applying the semiconductor laser chips on the carrier, the semiconductor laser chips and the carrier can be heated so that electrical contacts of the semiconductor laser chips and the carrier at least partially melt, and, thus, form connections between the electrical contacts of the semiconductor laser chips and the electrical contacts of the carrier. To improve the precision with which the semiconductor laser chips are positioned on the carrier, the carrier can comprise stop structures. The stop structures are designed to guide the semiconductor laser chips in a heated state into a predetermined position on the carrier. These stop structures can be recesses.

The semiconductor laser chips can also comprise structures that support this guiding process, i.e. a passive alignment. Thus, the electrical contacts of the semiconductor laser chips can be specially shaped by means of photolithography, or the semiconductor laser chips can comprise edges produced by etching that simplify an alignment on the carrier. For example, the semiconductor laser chips can comprise structures that allow the semiconductor laser chips to “float in” during soldering or to be mounted “on stop”. This simultaneously establishes mechanical and electrical contact with the carrier. This is also possible if the semiconductor laser chips are transferred with a stamp.

Furthermore, the carrier can comprise optical elements such as mirrors or gratings for guiding laser radiation from the semiconductor laser chips. Thus, the radiation emitted by the semiconductor laser chips during operation can be coupled into waveguides of the carrier. The semiconductor laser chips can also comprise an optical element such as a mirror, a lens, or a waveguide to improve the guidance of the laser radiation on the carrier.

According to at least one embodiment of the method, the laser chip regions are formed by removing the semiconductor layer in places by etching and by applying the first mirror and the second mirror on the second region. This can mean that for each laser chip region, a portion of the semiconductor layer is removed by etching. Thereby, for each laser chip region, a portion of the semiconductor layer around a resonator region is removed. This means, after the semiconductor layer has been removed in places by etching, the resonator region remains per laser chip region. In the area around the respective resonator region, a portion of the semiconductor layer is removed by etching. This means, after etching, the semiconductor layer is thinned in the area around the resonator region. However, it is possible that the semiconductor layer in the region around the resonator region is not completely removed. The resonator regions can each comprise the shape of a rectangle or strip parallel to the main extension plane of the semiconductor layer. The individual resonator regions are spaced apart from each other. Thus, the semiconductor layer comprises a greater extension in a vertical direction, which is perpendicular to the main extension plane of the semiconductor layer, in the region of the resonator regions than outside the resonator regions. Thereby, the second region of the semiconductor layer per laser chip region is the region of the semiconductor layer which extends in the vertical direction in the resonator region between the vertical position to which the semiconductor layer in the surrounding region has been removed and a top surface of the semiconductor layer facing away from the substrate. The first region of the semiconductor layer is the region of the semiconductor layer arranged below the first region in the growth direction. This means, per laser chip region, the first region of the semiconductor layer is the region which comprises a first extension parallel to the main extension plane of the semiconductor layer, wherein the first extension is larger than a second extension parallel to the main extension plane of the semiconductor layer, which the semiconductor layer comprises in the second region.

The first mirror and the second mirror are deposited on opposite sides of the second region. The sides on which the first mirror and the second mirror are deposited can be transverse or perpendicular to the main extension plane of the semiconductor layer. The first mirror and the second mirror can be formed as a result of depositing at least one layer, which comprises a metal, on the second region. The layer can be deposited by vapor deposition or sputtering. The laser chip regions can be formed simultaneously. Thus, advantageously, a plurality of semiconductor laser chips can be produced simultaneously with the method.

According to at least one embodiment of the method, the first region comprises a larger extension parallel to the main extension plane of the semiconductor layer than the second region. This means, that for each laser chip region, the first region comprises a larger extension parallel to the main extension plane of the semiconductor layer than the second region. Thereby, the resonators for the semiconductor laser chips are formed.

According to at least one embodiment of the method, the laser chip regions are formed by removing the semiconductor layer in places by etching and by depositing a third and a fourth mirror to the second region. The removal of the semiconductor layer in places by etching can be performed as described above. Then, the third mirror and the fourth mirror for each laser chip region are applied to the second region. Thereby, the third mirror and the fourth mirror extend parallel to the main extension plane of the semiconductor layer. The third mirror and the fourth mirror are thereby arranged on a side of the second region facing away from the substrate. The third mirror and the fourth mirror are spaced apart from each other. The third mirror and the fourth mirror can be formed by depositing at least one layer, which comprises a metal, on the second region. The layer can be deposited by vapor deposition or sputtering. The laser chip regions can be formed simultaneously. Thus, advantageously, a plurality of semiconductor laser chips can be produced simultaneously with the method.

According to at least one embodiment of the method, every nth one of the semiconductor laser chips is transferred to the carrier, wherein n is a natural number. This means that every nth one of the semiconductor laser chips is transferred to the carrier simultaneously. The remaining semiconductor laser chips can be transferred to further carriers in subsequent transfer steps. Thus, for example, in a further transfer step each nth of the remaining semiconductor laser chips can be transferred to a further carrier. It is possible that every nth semiconductor laser chip is transferred to the carrier and that the transfer process is repeated for n-1 further carriers. Thereby, it is possible to adjust which distance the semiconductor laser chips on the carrier comprise to each other. Thus, the semiconductor laser chips on the carrier comprise a larger distance to each other than on the auxiliary carrier if n is greater than 1.

According to at least one embodiment of the method, the support regions are formed by forming recesses in the sacrificial layer by removing the sacrificial layer in places by etching and by introducing the material of the support regions into the recesses. This means, the sacrificial layer is removed in places by etching. As a result, recesses are formed in the sacrificial layer. The recesses extend completely through the sacrificial layer. The material of the support regions is inserted into these recesses. The material of the support regions completely fills the recesses. Thus, the support regions are formed. Advantageously, the support regions can be used in the transfer process described herein.

According to at least one embodiment of the method, the sacrificial layer is deposited along the growth direction of the semiconductor layer above the semiconductor layer. That means, the sacrificial layer is deposited on a side of the semiconductor layer facing away from the substrate. On this side, electrical contacts of the respective laser chip region can be arranged. During the subsequent transfer process, this side faces the carrier, so that, advantageously, the electrical contacts can be connected with electrical contacts of the carrier.

According to at least one embodiment of the method, for each laser chip region the second region is removed in places so that the second region comprises two side edges which run transversely to the main extension plane of the semiconductor layer. For each laser chip region, the second region is removed in places after the application of the auxiliary carrier, so that the second region comprises two side edges which run transversely to the main extension plane of the semiconductor layer. The second region can, for each laser chip region, be removed in places by etching. The two side edges, which run transversely to the main extension plane of the semiconductor layer, are arranged on opposite sides of the second region. It is possible that also the first region is removed in places for each laser chip region, so that the first region comprises two side edges which run transverse to the main extension plane of the semiconductor layer. These two side edges of the first region can be arranged on the same sides of the semiconductor layer as the two side edges of the second region. Thus, the semiconductor layer can have a total of two side edges which run transverse to the main extension plane of the semiconductor layer.

The first region comprises a smaller extension parallel to the main extension plane of the semiconductor layer than the second region. On the two side edges of the second region, a first mirror and a second mirror can be applied. Thus, the first mirror is applied to the one of the two side edges and the second mirror is applied to the other of the two side edges. For this purpose, on each of the two side edges at least one layer comprising a metal can be deposited. The first mirror and the second mirror can completely cover the two side edges of the semiconductor layer, which run transverse to the main extension plane of the semiconductor layer. The first mirror can be an exit mirror. Thus, from these laser chip regions, advantageously, horizontal cavity surface emitting laser can be formed. This means that during operation of the semiconductor laser chips, the generated laser radiation exits at their top side. Advantageously, this enables easier coupling of the emitted laser radiation into optical elements of the carrier.

According to at least one embodiment of the method, recesses are formed between the laser chip regions for singulation of the laser chip regions into semiconductor laser chips. This means, between every two laser chip regions a recess is formed. The recess extends up to the sacrificial layer. Furthermore, the recesses each extend over the entire extension of the laser chip regions. Thus, the laser chip regions are completely surrounded by recesses parallel to the main extension plane of the semiconductor layer. Thus, the semiconductor laser chips are each arranged at a distance from each another and, thus, singulated.

According to at least one embodiment of the method, the semiconductor laser chips are connected with the auxiliary carrier exclusively via the support regions at the start of transferring. After removal of the sacrificial layer, the semiconductor laser chips are connected to the auxiliary carrier exclusively via the support regions. Thus, the semiconductor laser chips are connected to the auxiliary carrier exclusively via the support regions immediately before the transfer to the carrier. When a stamp is used for transferring the semiconductor laser chips, the semiconductor laser chips are connected to the auxiliary carrier exclusively via the support regions during the application of the stamp. The connection exclusively via the support regions enables easy separation of the auxiliary carrier from the semiconductor laser chips.

Further, a semiconductor laser chip is provided. The semiconductor laser chip is preferably manufacturable by a method described herein. In other words, all features disclosed for the method for producing a plurality of semiconductor laser chips are also disclosed for the semiconductor laser chip, and vice versa.

According to at least one embodiment of the semiconductor laser chip, the semiconductor laser chip comprises a semiconductor layer. The semiconductor layer can extend over the entire extension of the semiconductor laser chip parallel to the main extension plane of the semiconductor layer.

According to at least one embodiment of the semiconductor laser chip, the semiconductor laser chip comprises a first mirror and a second mirror.

According to at least one embodiment of the semiconductor laser chip, the semiconductor layer comprises a first region and a second region. The first region can be directly adjacent to the second region.

According to at least one embodiment of the semiconductor laser chip, the semiconductor layer comprises an active region which is arranged in the second region. The active region can extend over the entire extension of the second region parallel to the main extension plane of the semiconductor layer.

According to at least one embodiment of the semiconductor laser chip, the active region is arranged between the first mirror and the second mirror, wherein the first mirror and the second mirror are adjacent to the second region.

According to at least one embodiment of the semiconductor laser chip, the second region is arranged on the first region along a vertical direction, which runs perpendicular to the main extension plane of the semiconductor layer.

According to at least one embodiment of the semiconductor laser chip, the semiconductor laser chip comprises a semiconductor layer, a first mirror, and a second mirror, wherein the semiconductor layer comprises a first region and a second region, the semiconductor layer comprises an active region, which is arranged in the second region, the active region is arranged between the first mirror and the second mirror, wherein the first mirror and the second mirror are adjacent to the second region, and the second region is arranged on the first region along a vertical direction, which runs perpendicular to the main extension plane of the semiconductor layer.

The semiconductor laser chip can be manufactured by the method described herein. Thus, the semiconductor laser chip can be manufactured efficiently.

According to at least one embodiment of the semiconductor laser chip, the first region and the second region comprise different extensions from each other parallel to the main extension plane of the semiconductor layer. This is achieved by the semiconductor laser chip comprising side edges which run transversely to the main extension plane of the semiconductor layer or as a result of removing a portion of the semiconductor layer by etching prior to the deposition of the first mirror and the second mirror. Thus, the semiconductor laser chip can be manufactured by the method described herein. Thus, the semiconductor laser chip can be manufactured efficiently.

According to at least one embodiment of the semiconductor laser chip, the semiconductor laser chip comprises two electrical contacts, which are arranged on the same side of the semiconductor laser chip. This has the advantage that the semiconductor laser chip can be easily electrically contacted. For example, the semiconductor laser chip is applied to a carrier on whose surface electrical contacts are arranged. The electrical contacts of the semiconductor laser chip can be connected to these electrical contacts. A further electrical contacting on another side of the semiconductor laser chip is advantageously not necessary.

According to at least one embodiment of the semiconductor laser chip, an encapsulation is arranged on the side of the first mirror facing away from the second region. The encapsulation can completely cover the first mirror. The encapsulation can be at least partially transmissive to the laser radiation emitted by the semiconductor laser chip. The encapsulation can be used to be arranged in direct contact to a waveguide of a carrier. Thus, laser radiation emitted from the semiconductor laser chip can be coupled into a waveguide through the encapsulation.

According to at least one embodiment of the semiconductor laser chip, the first mirror is free of an encapsulation. This can mean that the first mirror is arranged on an outer side of the semiconductor laser chip. Laser radiation of the semiconductor laser chip emitted from the first mirror exits the semiconductor laser chip. Since no encapsulation is used, reflections at an encapsulation are avoided.

According to at least one embodiment of the semiconductor laser chip, the semiconductor laser chip comprises an extension of at most 500 μm in a plane, which runs parallel to the main extension plane of the semiconductor layer. Preferably, the semiconductor laser chip comprises an extension of at most 300 μm in a plane, which runs parallel to the main extension plane of the semiconductor layer. Particularly preferably, the semiconductor laser chip comprises an extension of at most 200 μm in a plane, which runs parallel to the main extension plane of the semiconductor layer. With these sizes of the semiconductor laser chip, it is possible to simultaneously manufacture a large number of semiconductor laser chips on a relatively small area.

According to at least one embodiment of the semiconductor laser chip, the first region comprises a larger extension parallel to the main extension plane of the semiconductor layer than the second region. This means, that the first region comprises a larger extension parallel to the main extension plane of the semiconductor layer than the second region. As a result, a resonator region of the semiconductor laser chip can be formed in the second region.

According to at least one embodiment of the semiconductor laser chip, the first mirror and the second mirror each comprise a main extension plane, which runs perpendicular to the main extension plane of the semiconductor layer. Thereby, the first mirror and the second mirror can be arranged on opposite sides of the second region. Thus, a resonator of the semiconductor laser chip can be formed with the first mirror, the second mirror and the second region.

According to at least one embodiment of the semiconductor laser chip, the first mirror comprises a lower reflectivity than the second mirror. The first mirror can be an exit mirror of the semiconductor laser chip. The first mirror can comprise a reflectivity of less than 50%. The second mirror can comprise a reflectivity of more than 80%. Thus, the semiconductor laser chip can generate laser radiation during operation and this can be coupled out of the semiconductor laser chip through the first mirror.

According to at least one embodiment of the semiconductor laser chip, the semiconductor layer comprises two side edges which extend transversely to the main extension plane of the semiconductor layer. The two side edges can each include an angle of at least 40° and at most 50° with the main extension plane of the semiconductor layer. The two side edges can be arranged on opposite sides of the semiconductor layer. The two side edges allow for the semiconductor laser chip comprising mirrors extending transversely to the main extension plane of the semiconductor layer.

According to at least one embodiment of the semiconductor laser chip, the semiconductor laser chip comprises a third mirror and a fourth mirror, which are both arranged on the side of the semiconductor layer where the semiconductor layer comprises the largest extension parallel to its main extension plane, wherein the third mirror and the fourth mirror each comprise a main extension plane, which is parallel to the main extension plane of the semiconductor layer. The third mirror and the fourth mirror are spaced apart from each other. The third mirror and the fourth mirror can be formed by depositing at least one layer, which comprises a metal, on the first region or on the second region. The layer can be deposited by vapor deposition or sputtering. The side of the semiconductor layer on which the third mirror and the fourth mirror are arranged extends at least in places parallel to the main extension plane of the semiconductor layer. With this structure of the semiconductor laser chip, a surface-emitting laser can be realized.

According to at least one embodiment of the semiconductor laser chip, the third mirror comprises a lower reflectivity than the fourth mirror and the first region comprises a larger extension parallel to the main extension plane of the semiconductor layer than the second region. The third mirror can be an exit mirror of the semiconductor laser chip. The third mirror can comprise a reflectivity of less than 50%.

The fourth mirror can comprise a reflectivity of more than 80%. Thus, the semiconductor laser chip can generate laser radiation during operation and this can be coupled out of the semiconductor laser chip through the third mirror. Thereby, the active region is arranged between the first mirror and the second mirror. The first mirror and the second mirror can each extend transversely or at an angle of at least 40° and at most 50° with respect to the main extension plane of the semiconductor layer. The first mirror and the second mirror can each comprise a higher reflectivity than the third mirror.

Electromagnetic radiation impinging on the second mirror is at least partially reflected to the fourth mirror. From there, the impinging electromagnetic radiation is at least partially reflected back to the second mirror. From there, the impinging electromagnetic radiation is at least partially reflected to the first mirror. From there, the impinging electromagnetic radiation is at least partially reflected to the third mirror, where it is either reflected or exits the semiconductor laser chip. Thus, the laser radiation generated by the semiconductor laser chip exits from the semiconductor laser chip perpendicular to the main extension plane of the semiconductor layer.

According to at least one embodiment of the semiconductor laser chip, the first mirror and the second mirror each comprise a main extension plane, which runs transverse to the main extension plane of the semiconductor layer, and the third mirror comprises a lower reflectivity than the fourth mirror. Moreover, the semiconductor layer comprises two side edges which run transversely to the main extension plane of the semiconductor layer. The first mirror and the second mirror are arranged at these two side edges. Thus, the first mirror and the second mirror are arranged on opposite sides of the semiconductor layer. The first mirror and the second mirror can be adjacent to the first region and the second region, respectively. The third mirror and the fourth mirror each extend parallel to the main extension plane of the semiconductor layer. The third mirror can be an exit mirror of the semiconductor laser chip. The third mirror can comprise a reflectivity of less than 50%. The fourth mirror can comprise a reflectivity of more than 80%. Thus, the semiconductor laser chip can generate laser radiation during operation and this radiation can be coupled out of the semiconductor laser chip through the third mirror. Thus, the laser radiation generated by the semiconductor laser chip exits from the semiconductor laser chip perpendicular to the main extension plane of the semiconductor layer.

According to at least one embodiment of the semiconductor laser chip, the first region comprises a smaller extension parallel to the main extension plane of the semiconductor layer than the second region. This shape can be due to the transverse side edges of the semiconductor layer.

Furthermore, a semiconductor laser chip system with at least one semiconductor laser chip and at least one waveguide is provided, wherein a radiation exit surface of the semiconductor laser chip is optically connected to the waveguide. The radiation exit surface can be the surface from which laser radiation emitted from the semiconductor laser chip during operation exits the semiconductor laser chip. That the radiation exit surface of the semiconductor laser chip is optically connected to the waveguide can mean, that the radiation exit surface of the semiconductor laser chip is optically coupled to the waveguide. Thus, at least a portion of the laser radiation emitted from the semiconductor laser chip during operation is coupled into the waveguide. The waveguide can be arranged spaced apart from the semiconductor laser chip or can be in direct contact with the semiconductor laser chip. The semiconductor laser chip system can be a photonic integrated circuit (PIC), or the semiconductor laser chip system can comprise a photonic integrated circuit (PIC). The semiconductor laser chip system can comprise a plurality of semiconductor laser chips. The semiconductor laser chip system can further comprise the carrier described herein. The semiconductor laser chip or the plurality of semiconductor laser chips is arranged on the carrier.

In the following, the method for producing a plurality of semiconductor laser chips described herein and the semiconductor laser chip described herein are explained in more detail in connection with exemplary embodiments and the accompanying figures.

### BRIEF DESCRIPTION OF THE DRAWINGS

FIGS. 1A, 1B, 1C and 1D show exemplary embodiments of the semiconductor laser chip.

With the FIGS. 2, 3, 4A, 4B, 5A, 5B, 5C, 6, 7, 8, 9, 10, 11, 12, 13, 14, 15, 16, 17, 18, 19, 20, 21, 22, 23, 24A, 24B, and 24C, various exemplary embodiments of the method for producing a plurality of semiconductor laser chips are described.

### DETAILED DESCRIPTION

Elements that are identical, similar or have the same effect are given the same reference signs in the figures. The figures and the proportions of the elements shown in the figures are not to be regarded as to scale. Rather, individual elements can be shown exaggeratedly large for better representability and/or for a better comprehensibility.

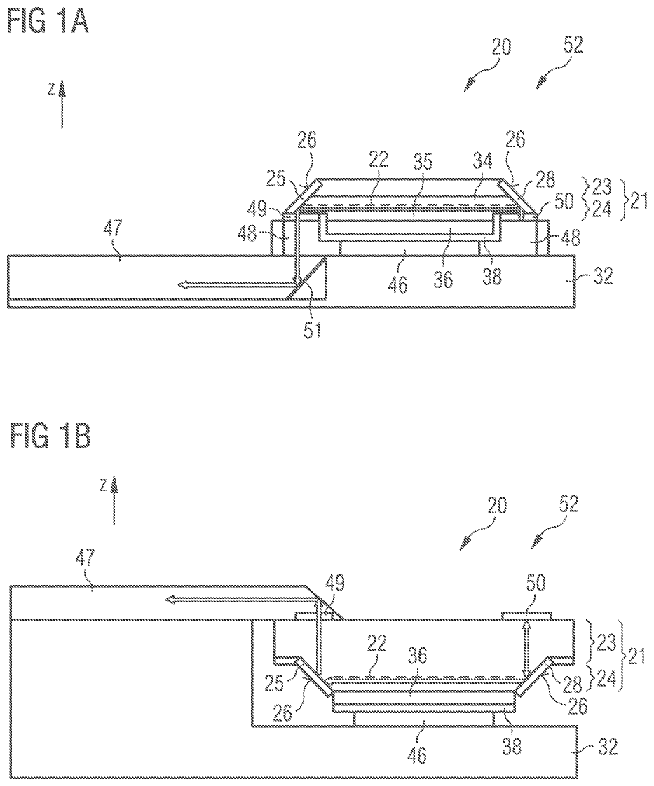

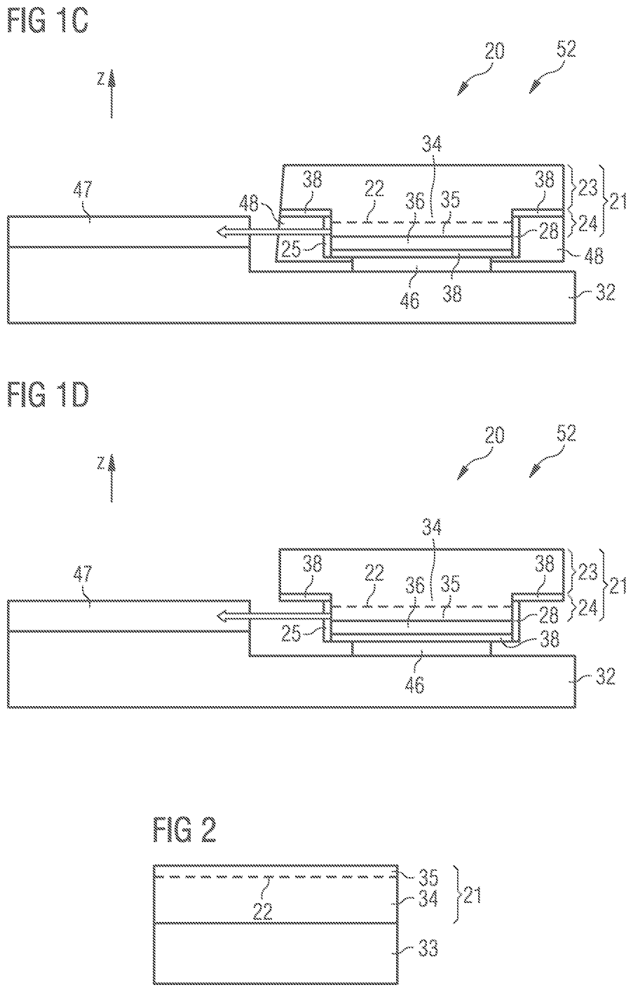

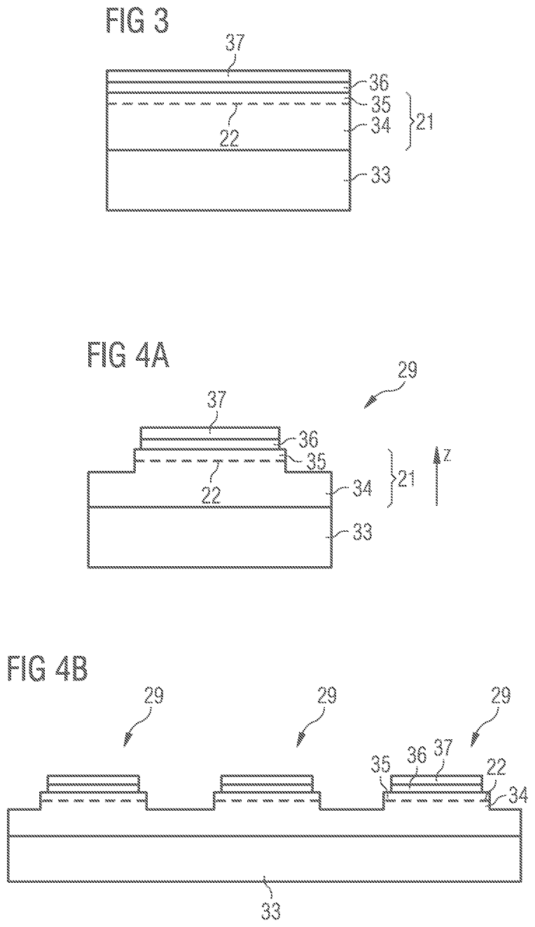

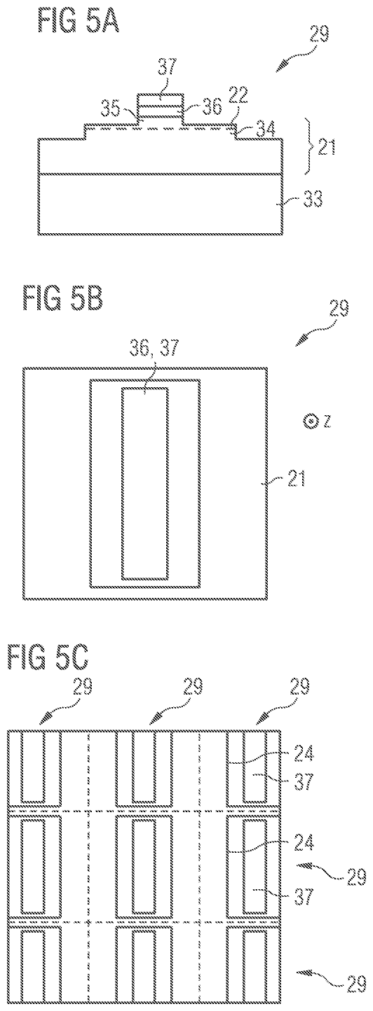

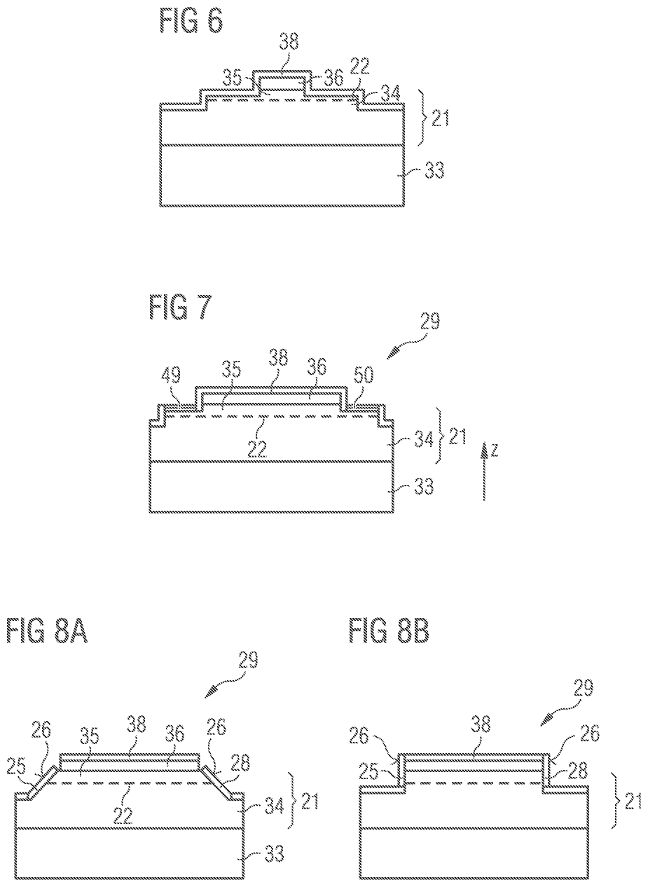

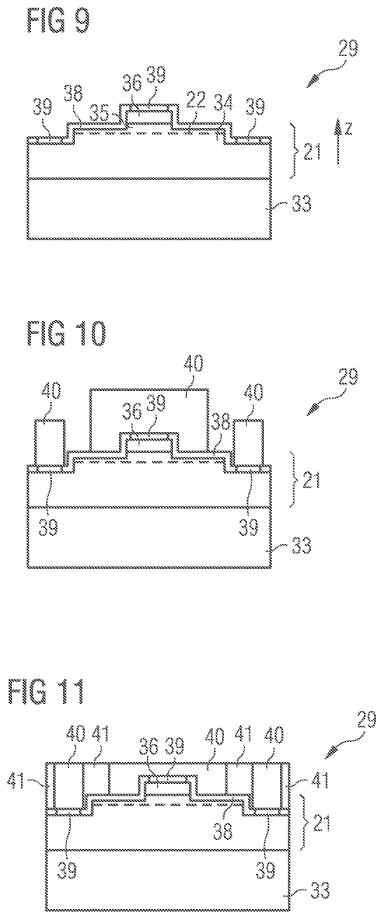

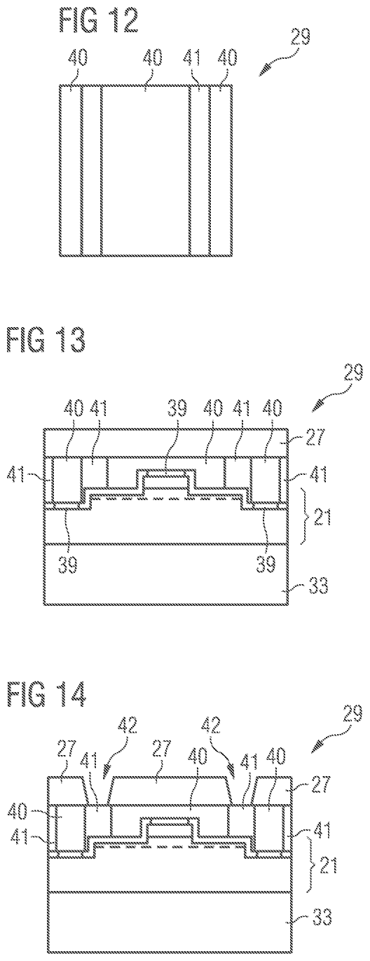

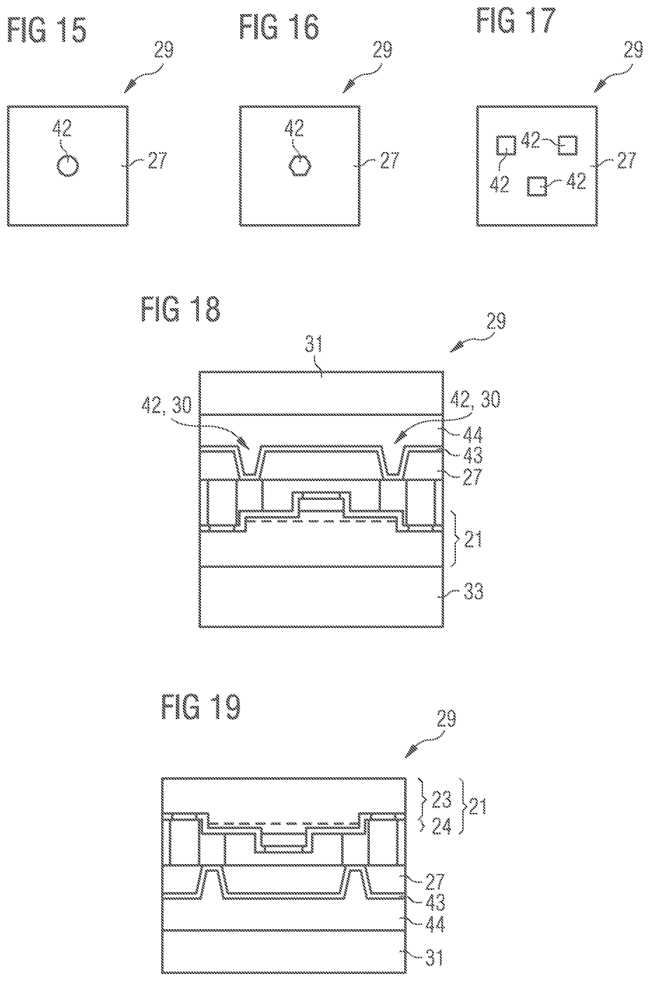

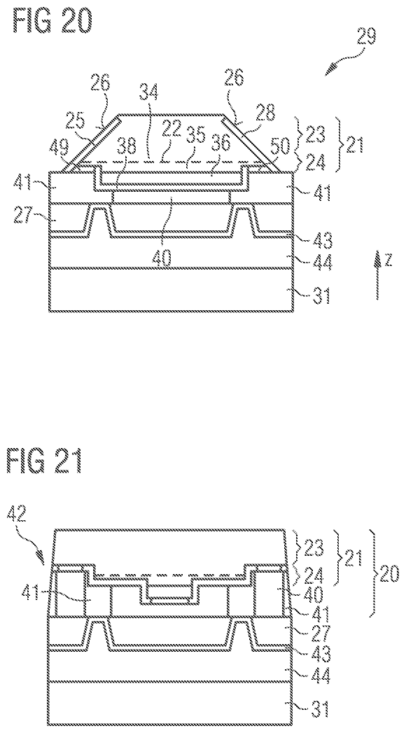

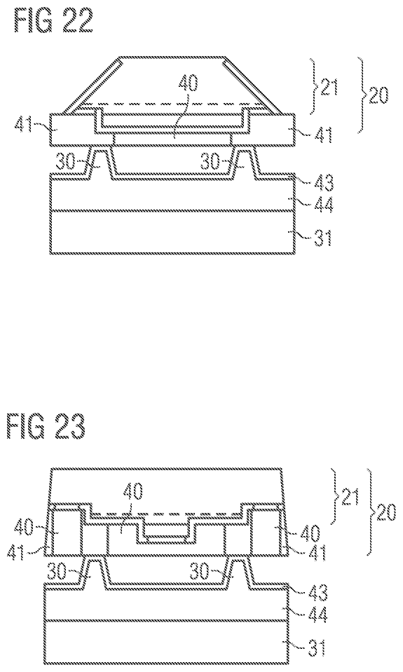

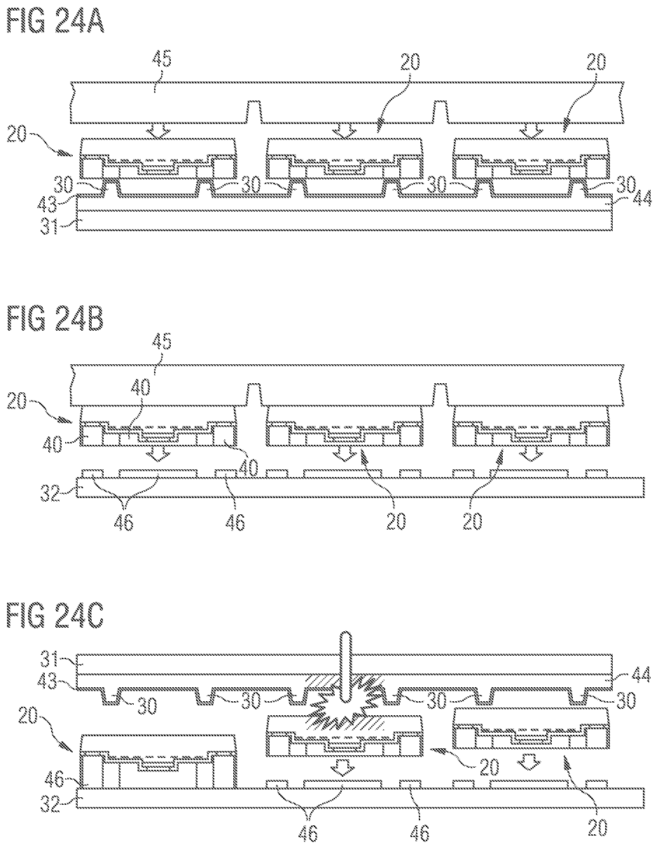

FIG. 1A shows a schematic cross-sectional view of a semiconductor laser chip 20 according to an exemplary embodiment. The semiconductor laser chip 20 is arranged on a carrier 32. The semiconductor laser chip 20 comprises a semiconductor layer 21 with a first region 23 and a second region 24. An active region 22 of the semiconductor layer 21 is arranged in the second region 24. In the second region 24, the semiconductor layer 21 comprises an n-doped region 34 and a p-doped region 35. The n-doped region 34 and the p-doped region 35 are arranged one above the other in a vertical direction z, wherein the vertical direction z extends perpendicular to the main extension plane of the semiconductor layer 21. The active region 22 is arranged between the n-doped region 34 and the p-doped region 35.

The semiconductor layer 21 comprises two side edges 26 which run transversely or at an angle of at least 40° and at most 50° to the main extension plane of the semiconductor layer 21. The two side edges 26 are arranged on opposite sides of the semiconductor layer 21. A first mirror 25 and a second mirror 28 of the semiconductor laser chip 20 are arranged at the side edges 26. Thus, the first mirror 25 is arranged at one of the two side edges 26 and the second mirror 28 is arranged at the other of the two side edges 26. Thus, the active region 22 is arranged between the first mirror 25 and the second mirror 28. The first mirror 25 and the second mirror 28 are adjacent to the second region 24. The second region 24 is arranged along the vertical direction z on the first region 23. In FIG. 1A, the semiconductor laser chip 20 is shown rotated 180°. Thus, in FIG. 1A, the first region 23 is arranged above the second region 24. The first region 23 and the second region 24 comprise different extensions from each other parallel to the main extension plane of the semiconductor layer 21. Thus, the first region 23 comprises a smaller extension parallel to the main extension plane of the semiconductor layer 21 than the second region 24.

The semiconductor laser chip 20 further comprises a third mirror 49 and a fourth mirror 50. The third mirror 49 and the fourth mirror 50 are both arranged on the side of the semiconductor layer 21 where the semiconductor layer 21 comprises the largest extension parallel to its main extension plane. The third mirror 49 and the fourth mirror 50 are arranged adjacent to the second region 24. The third mirror 49 and the fourth mirror 50 each comprise a main extension plane which runs parallel to the main extension plane of the semiconductor layer 21.

The third mirror 49 comprises a lower reflectivity than the fourth mirror 50. Thus, the third mirror 49 is an exit mirror of the semiconductor laser chip 20.

The semiconductor laser chip 20 comprises an extension of at most 500 μm in a plane, which runs parallel to the main extension plane of the semiconductor layer 21.

A contact layer 36 is arranged on the side of the second region 24 facing away from the first region 23. The contact layer 36 is electrically conductive. The contact layer 36 covers the region of the side of the second region 24 facing away from the first region 23, which is arranged between the third mirror 49 and the fourth mirror 50. A passivation layer 38 is arranged on the side of the contact layer 36 facing away from the second region 24. An electrical contact 46 is arranged on the side of the passivation layer 38 facing away from the contact layer 36. The electrical contact 46 is arranged on the carrier 32. The sides of the third mirror 49 and the fourth mirror 50 facing away from the semiconductor layer 21 are each covered with an encapsulation 48. Thereby, the encapsulation 48 extends to the carrier 32. A waveguide 47 is arranged on the carrier 32. The waveguide 47 is directly adjacent to the encapsulation 48, which is adjacent to the third mirror 49. In the waveguide 47, a fifth mirror 51 is arranged, which extends at an angle of 45° with respect to the main extension plane of the semiconductor layer 21. Thus, laser radiation which exits the semiconductor laser chip 20 through the third mirror 49 can pass through the encapsulation 48, enter the waveguide 47, be reflected at the fifth mirror 51, and then propagate further parallel to the main extension plane of the semiconductor layer 21.

Electromagnetic radiation generated in the active region 22 can be reflected from the second mirror 28 to the fourth mirror 50. From there, the electromagnetic radiation can be reflected back to the second mirror 28. There, the electromagnetic radiation can be reflected to the first mirror 25. From there, electromagnetic radiation can be reflected at the third mirror 49 or exit the semiconductor laser chip 20 through the third mirror 49.

FIG. 1B shows a schematic cross-section through a semiconductor laser chip 20 according to a further exemplary embodiment. The semiconductor laser chip 20 is also arranged on a carrier 32. In contrast to the exemplary embodiment shown in FIG. 1A, the first region 23 comprises parallel to the semiconductor layer 21 a larger extension than the second region 24. Furthermore, only portions of the side edges 26 of the semiconductor layer 21 extend transversely to the main extension plane of the semiconductor layer 21. The first region 23 is the region in which the side edges 26 of the semiconductor layer 21 extend perpendicularly to the main extension plane of the semiconductor layer 21. The second region 24 is the region in which the side edges 26 of the semiconductor layer 21 extend transversely to the main extension plane of the semiconductor layer 21. Thus, the first region 23 comprises a larger extension parallel to the main extension plane of the semiconductor layer 21 than the second region 24.

The third mirror 49 and the fourth mirror 50 are arranged on the side of the first region 23 facing away from the second region 24. The third mirror 49 and the fourth mirror 50 extend parallel to the main extension plane of the semiconductor layer 21. The third mirror 49 comprises a lower reflectivity than the fourth mirror 50. Thus, the third mirror 49 is an exit mirror of the semiconductor laser chip 20.

Directly adjacent to the third mirror 49, a waveguide 47 of the carrier 32 is arranged. Thus, laser radiation emitted from the semiconductor laser chip 20 can enter the waveguide 47. The first mirror 25 and the second mirror 28 are free of an encapsulation 48.

FIG. 1C shows a cross-section through a further exemplary embodiment of the semiconductor laser chip 20. The semiconductor laser chip 20 is arranged on a carrier 32. The semiconductor layer 21 comprises the first region 23, which comprises a larger extension parallel to the main extension plane of the semiconductor layer 21 than the second region 24. The first mirror 25 and the second mirror 28 are arranged adjacent to the second region 24. Thereby, the first mirror 25 and the second mirror 28 each comprise a main extension plane, which runs perpendicular to the main extension plane of the semiconductor layer 21. The first mirror 25 comprises a lower reflectivity than the second mirror 28. The first mirror 25 is an exit mirror of the semiconductor laser chip 20. The active region 22 is arranged between the first mirror 25 and the second mirror 28. An encapsulation 48 is arranged at the side of the first mirror 25 facing away from the second region 24. Moreover, an encapsulation 48 is arranged at the side of the second mirror 28 facing away from the second region 24.

The semiconductor laser chip 20 is arranged spaced apart from a waveguide 47 of the carrier 32. Thus, laser radiation exiting the first mirror 25 can exit the semiconductor laser chip 20 and subsequently enter the waveguide 47.

FIG. 1D shows a schematic cross-section through a further exemplary embodiment of the semiconductor laser chip 20. The only difference from the exemplary embodiment shown in FIG. 1C is that the semiconductor laser chip 20 does not comprise an encapsulation 48.

FIGS. 1A, 1B, 1C, and 1D each further show a semiconductor laser chip system 52 with a semiconductor laser chip 20, a waveguide 47, and a carrier 32. A radiation exit surface of the semiconductor laser chip 20 is optically connected to the waveguide 47. By way of example, only one semiconductor laser chip 20 is shown in each case, but the semiconductor laser chip system 52 can comprise a plurality of semiconductor laser chips 20.

With the FIGS. 2 to 24C, various exemplary embodiments of the method for producing a plurality of semiconductor laser chips 20 are described.

FIG. 2 shows a first method step. Thereby, a semiconductor layer 21 with an active region 22 is grown. The semiconductor layer 21 is grown on a substrate 33. The semiconductor layer 21 comprises an n-doped region 34 and a p-doped region 35. The n-doped region 34 is arranged on the substrate 33. The p-doped region 35 is arranged on the n-doped region 34. The active region 22 is arranged between the n-doped region 34 and the p-doped region 35.

FIG. 3 shows a next method step. Thereby, an electrically conductive contact layer 36 is applied to the semiconductor layer 21. The contact layer 36 completely covers the semiconductor layer 21. On the contact layer 36, a mask 37 is applied, which completely covers the contact layer 36.

FIG. 4A shows a next method step. Here, a part of the semiconductor layer 21 is removed by etching. For this, a further mask is applied to a region of the mask 37 and a part of the mask 37 and a part of contact layer 36 are removed in a photolithography process by means of wet etching. Subsequently, using dry etching, a portion of the semiconductor layer 21 is removed. As a result, individual regions of the semiconductor layer 21 are formed which extend further in the vertical direction z than the remaining regions. FIG. 4A shows an example of how a laser chip region 29 is formed. The laser chip region 29 comprises a portion of the active region 22 and a portion of the semiconductor layer 21.

In FIG. 4B, it is shown that multiple laser chip regions 29 are formed adjacent to each other. In FIG. 4B, three laser chip regions 29 are shown as an example. However, it is also possible that a plurality of laser chip regions 29 are formed on the substrate 33. Thereby, the laser chip regions 29 can be arranged at grid points of a 2-dimensional grid. In this case, the laser chip regions 29 are directly adjacent to each other. Each laser chip region 29 is configured to be further developed into a semiconductor laser chip 20.

FIG. 5A shows a next step of the method. Thereby, a further photolithography step for each laser chip region 29 a portion of the semiconductor layer 21, namely a portion of the p-doped region 35 is removed. FIG. 5A shows the laser chip region 29 from a different direction than in FIGS. 4A and 4B. FIG. 5A shows the laser chip region 29 from a side to which a mirror of the semiconductor laser chip 20 is later applied.

In FIG. 5B a top view of the step shown in FIG. 5A is shown. Thereby, a view on the semiconductor layer 21 is shown. The contact layer 36 and the mask 37 are arranged on this layer. After the etching processes, the contact layer 36 and the mask 37 comprise the shape of a rectangle or strip. The dashed line marks the region in which the semiconductor layer 21 comprises a larger extension in the vertical direction z than in other regions.

In FIG. 5C a further top view of the step shown in FIG. 5A is shown. Thereby, a plurality of laser chip regions 29 is shown, which are arranged next to each other in a 2-dimensional array.

In FIG. 6 a next step of the method is shown. Here, a passivation layer 38 is applied to the semiconductor layer 21 and the contact layer 36. The mask 37 has been removed. The passivation layer 38 comprises a dielectric material such as SiO₂ or SiN, for example.

FIG. 7 shows a next step of the method. Here, a laser chip region 29 is shown from the same view as in FIG. 4A. According to this exemplary embodiment, a third mirror 49 and a fourth mirror 50 are deposited on the semiconductor layer 21. For this purpose, the passivation layer 38 is first removed in places. The third mirror 49 and the fourth mirror 50 are applied to the regions of the semiconductor layer 21 which comprise a larger extension in the vertical direction z and are not covered by the contact layer 36. The third mirror 49 comprises a lower reflectivity than the fourth mirror 50. From the laser chip region 29 shown in FIG. 7, the semiconductor laser chip 20 of FIG. 1A can be produced.

In FIG. 8A an alternative to the method step of FIG. 7 is shown. Thereby, the passivation layer 38 is removed from the semiconductor layer 21 in places. Subsequently, two side edges 26 of the semiconductor layer 21 are formed, which extend transversely to the main extension plane of the semiconductor layer 21. The two side edges 26 are arranged on opposite sides of the semiconductor layer 21. A first mirror 25 is applied to one of the two side edges 26, and a second mirror 28 is applied to the other of the two side edges 26. It is further possible that all side edges 26 of the semiconductor layer 21 run transversely to the main extension plane of the semiconductor layer 21 and that a mirror 25, 28 is applied to each side edge 26. Thus, the mirrors 25, 28 can be arranged circumferentially around the central region of the laser chip region 29. From the laser chip region 29 shown in FIG. 8A, the semiconductor laser chip 20 of FIG. 1B can be manufactured.

In FIG. 8B an alternative to the method steps of FIGS. 7 and 8A is shown. Here, the passivation layer 38 is removed by etching at side edges 26 of the semiconductor layer 21 extending perpendicular to the main extension plane of the semiconductor layer 21. The passivation layer 38 is removed in places in a photolithography step. Then, a first mirror 25 and a second mirror 28 are applied on the side edges 26 of the semiconductor layer 21 extending perpendicularly to the main extension plane of the semiconductor layer 21. This can be done in one photolithography step or in two separate photolithography steps. The first mirror 25 comprises a lower reflectivity than the second mirror 28. From the laser chip region 29 shown in FIG. 8B, the semiconductor laser chip 20 of FIGS. 1C and 1D can be manufactured.

It is also possible to perform the method step shown in FIG. 6 only after the method steps shown in FIGS. 7, 8A and 8B.

In FIG. 9 a next method step is shown. The following method steps can be performed for the three exemplary embodiments shown in FIGS. 7, 8A and 8B. By way of example, the next method steps are shown for the exemplary embodiment of FIG. 8B. Thereby, the passivation layer 38 is removed in places. The passivation layer 38 is removed in a further photolithography step above the contact layer 36 and on regions of the semiconductor layer 21 which comprise the smallest extension in the vertical direction z. Contact regions 39 are applied in the regions, in which the passivation layer 38 has been removed. The contact regions 39 are electrically conductive and comprise, for example, a metal. Each laser chip region 29 comprises a total of three contact regions 39, which each comprise the shape of a rectangle or strip. Thus, one of the contact regions 39 is in direct contact with the contact layer 36 and then with the p-doped region 35 and the other two contact regions 39 are in direct contact with the n-doped region 34.

In FIG. 10 a next method step is shown. Here, a solder metal 40 is applied to the contact regions 39 by photolithography. Thus, each laser chip region 29 comprises three regions of solder metal 40.

In FIG. 11 a next method step is shown. Here, a filling material 41 is applied between the regions with the solder metal 40. With the filling material 41 and the solder metal 40 together, the entire surface of the semiconductor layer 21 is covered. The filling material 41 can comprise a dielectric material. Subsequently, the laser chip region 29 is planarized at the side where the solder metal 40 and the filling material 41 are arranged. Alternatively, it is possible that the region adjacent to the first mirror 25 is filled with a sacrificial layer 27 instead of the filling material 41.

In FIG. 12 a top view of the method step of FIG. 11 is shown. Thereby, the three regions of solder metal 40 and the filling material 41 arranged in between are shown.

FIG. 13 shows a next method step. Thereby, a sacrificial layer 27 is deposited on the planarized surface of the laser chip region 29. This means, the sacrificial layer 27 is deposited along the growth direction of the semiconductor layer 21 above the semiconductor layer 21.

FIG. 14 shows a next method step. Thereby, in a photolithography step, recesses 42 are formed in the sacrificial layer 27. By way of example, it is shown that two recesses 42 are formed per laser chip region 29. However, it is sufficient that one recess 42 is formed.

In FIG. 15 a top view of the method step from FIG. 14 is shown. Here, the sacrificial layer 27 for a laser chip region 29 is shown with a recess 42. The recess 42 comprises the shape of a circle in the top view.

In FIG. 16 a further top view of the method step from FIG. 14 according to a further exemplary embodiment is shown. Here, the sacrificial layer 27 for a laser chip region 29 is shown with a recess 42. The recess 42 comprises the shape of a rectangle in the top view.

FIG. 17 shows a further top view of the method step from FIG. 14 according to a further exemplary embodiment. Here, the sacrificial layer 27 for a laser chip region 29 is shown with three recesses 42. The recesses 42 each comprise the shape of a square in the top view.

FIG. 18 shows a next method step. Here, an etch stop layer 43 is applied on the sacrificial layer 27 and the recesses 42. The etch stop layer 43 completely covers the recesses 42. A connection layer 44 is applied to the etch stop layer 43. The connection layer 44 completely covers the etch stop layer 43 and fills the recesses 42. Each recess 42 filled with the connection layer 44 forms a support region 30 in the sacrificial layer 27. An auxiliary carrier 31 is applied to the connection layer 44. Thus, the auxiliary carrier 31 is mechanically connected to the laser chip region 29 via the connection layer 44. Thereby, an auxiliary carrier 31 is used, which covers all laser chip regions 29. Thus, all laser chip regions 29 are arranged on the same auxiliary carrier 31.

FIG. 19 shows a next method step. In this step, the entire assembly is rotated by 180°, so that the auxiliary carrier 31 is located at the very bottom in the illustration of FIG. 19. Moreover, the substrate 33 is removed or at least thinned. The substrate 33 can be removed or thinned by grinding and/or polishing. The semiconductor layer 21 comprises for each laser chip region 29 a second region 24, which is arranged on a first region 23 of the semiconductor layer 21. Thereby, the first region 23 is the region where the semiconductor layer 21 comprises its largest extension parallel to the main extension plane of the semiconductor layer 21. The second region 24 is the region in which the semiconductor layer 21 comprises its smallest extension parallel to the main extension plane of the semiconductor layer 21. Thus, the laser chip regions 29 are formed by removing the semiconductor layer 21 in places by etching and by applying the first mirror 25 and the second mirror 28 to the second region 24, and the first region 23 comprises a larger extension parallel to the main extension plane of the semiconductor layer 21 than the second region 24.

In FIG. 20 a next method step is shown. This shows the construction of a laser chip region 29 from which the semiconductor laser chip 20 of FIG. 1A can be manufactured. After the removal of the substrate 33, a portion of the semiconductor layer 21 is removed in a photolithography step. Thereby, side edges 26 are formed which run transversely to the main extension plane of the semiconductor layer 21. The side edges 26 extend over the entire extent of the semiconductor layer 21 in vertical direction z. Thus, the semiconductor layer 21 comprises a second region 24 of the semiconductor layer 21 around the active region 22. A first region 23 of the semiconductor layer 21 is arranged above the second region 24 of the semiconductor layer 21. The first region 23 thus comprises a smaller extension parallel to the main extension plane of the semiconductor layer 21 than the second region 24. A first mirror 25 is applied to one of the two side edges 26, and a second mirror 28 is applied to the other of the two side edges 26. Both mirrors 25, 28 can comprise the same or a similar reflectivity. Adjacent to the third mirror 49 and the fourth mirror 50, the filling material 41 is arranged. Thus, the laser chip regions 29 are formed by removing the semiconductor layer 21 in places by etching and by applying a third mirror 49 and a fourth mirror 50 on the second region 24, and the second region 24 comprises a larger extension parallel to the main extension plane of the semiconductor layer 21 than the first region 23.

FIG. 21 shows a next method step for the exemplary embodiment shown in FIG. 19. Thereby, the laser chip regions 29 on the auxiliary carrier 31 are singulated into semiconductor laser chips 20. For this purpose, all layers up to the sacrificial layer 27 are separated in a photolithography step. Thus, recesses 42 are formed between the laser chip regions 29. Thereby, each semiconductor laser chip 20 comprises the first region 23 and the second region 24 of the semiconductor layer 21. The first mirror 25 and the second mirror 28, which are not shown in FIG. 21, are adjacent to the second region 24.

In FIG. 22 a next method step for the exemplary embodiment shown in FIG. 20 is shown. After singulating the laser chip regions 29 into semiconductor laser chips 20, the sacrificial layer 27 is removed. The sacrificial layer 27 can be removed by etching. Thus, the semiconductor laser chips 20 are each connected to the auxiliary carrier 31 exclusively via the support regions 30.

FIG. 23 shows a next method step for the exemplary embodiment shown in FIG. 21. Thereby, the sacrificial layer 27 is removed as shown with FIG. 22.

FIG. 24A shows a next method step which can be performed in this manner for all exemplary embodiments of the semiconductor laser chips 20. Thereby, at least some of the semiconductor laser chips 20 are transferred to a carrier 32 simultaneously. At the beginning of transferring, the semiconductor laser chips 20 are connected to the auxiliary carrier 31 exclusively via the support regions 30. Transferring takes place with a stamp 45, which is reversibly connected to the side of some of the semiconductor laser chips 20 facing away from the auxiliary carrier 31. In FIG. 24A, three semiconductor laser chips 20 are shown as examples. However, transfer is also possible for a plurality of the semiconductor laser chips 20 or for all of the semiconductor laser chips 20.

In FIG. 24B a next method step is shown. The auxiliary carrier 31 was removed from the semiconductor laser chips 20. Advantageously, this can be done easily since the semiconductor laser chips 20 were only connected to the auxiliary carrier 31 via the relatively small support regions 30. Next, the stamp 45 with the semiconductor laser chips 20 is positioned above the carrier 32. Then, the semiconductor laser chips 20 are aligned on electrical contacts 46 of the carrier 32 and the stamp 45 is removed. To make an electrical and mechanical connection between electrical contacts of the semiconductor laser chips 20, which are formed by the solder metal 40, and the electrical contacts 46 of the carrier 32, the entire system can be heated so that the electrical contacts 46 and the solder metal 40 melt and form a bond.

FIG. 24C shows an alternative method step. According to this exemplary embodiment, a stamp 45 is not used as shown in FIGS. 24A and 24B, but the transferring comprises a laser-induced transfer. Thereby, the connection between at least some of the semiconductor laser chips 20 and the auxiliary carrier 31 is released with the aid of a laser. Thereby, the semiconductor laser chips 20 are positioned on the carrier 32.

For both exemplary embodiments, that of FIGS. 24A and 24B and that of FIG. 24C, it is possible that every nth semiconductor laser chip 20 is transferred to the carrier 32, wherein n is a natural number.

The features and exemplary embodiments described in connection with the figures can be combined with each other according to further exemplary embodiments, even if not all combinations are explicitly described. Furthermore, the exemplary embodiments described in connection with the figures can alternatively or additionally comprise further features according to the description in the general part.

The invention is not limited to the exemplary embodiments by the description based on the exemplary embodiments. Rather, the invention encompasses any new feature as well as any combination of features, which in particular includes any combination of features in the patent claims, even if this feature or combination itself is not explicitly stated in the patent claims or exemplary embodiments.

1. A method for producing a plurality of semiconductor laser chips, the method comprising:
growing a semiconductor layer with an active region,
forming of a plurality of laser chip regions, wherein each laser chip region comprises a portion of the active region, a portion of the semiconductor layer, a first mirror and a second mirror,
depositing a sacrificial layer on the laser chip regions,
forming of at least one support region per laser chip region within the sacrificial layer,
depositing an auxiliary carrier on the sacrificial layer,
singulating the laser chip regions into semiconductor laser chips on the auxiliary carrier, wherein each semiconductor laser chip comprises a first region of the semiconductor layer and a second region of the semiconductor layer, wherein the first mirror and the second mirror are adjacent to the second region,
removing the sacrificial layer, and
simultaneously transferring at least some of the semiconductor laser chips onto a carrier, wherein
the support regions are formed by forming recesses in the sacrificial layer by removing the sacrificial layer in places by etching and by introducing the material of the support regions into the recesses.

2. The method for producing a plurality of semiconductor laser chips according to claim 1, wherein the transferring is performed with a stamp, which is reversibly connected to the side facing away from the auxiliary carrier of at least some of the semiconductor laser chips.

3. The method for producing a plurality of semiconductor laser chips according to claim 1, wherein the transferring comprises a laser-induced transfer in which the connection between at least some of the semiconductor laser chips and the auxiliary carrier is released by means of a laser.

4. The method for producing a plurality of semiconductor laser chips according to claim 1, wherein the laser chip regions are formed by removing the semiconductor layer in places by etching and by applying the first mirror and the second mirror to the second region, and wherein the first region comprises a larger extension parallel to the main extension plane of the semiconductor layer than the second region.

5. The method for producing a plurality of semiconductor laser chips according to claim 1, wherein the laser chip regions are formed by removing the semiconductor layer in places by etching and by depositing a third mirror and a fourth mirror to the second region, and wherein the second region comprises a larger extension parallel to the main extension plane of the semiconductor layer than the first region.

6. The method for producing a plurality of semiconductor laser chips according to claim 1, wherein every nth one of the semiconductor laser chips is transferred onto the carrier, wherein n is a natural number.

7. The method for producing a plurality of semiconductor laser chips according to claim 1, wherein the sacrificial layer is deposited along the growth direction of the semiconductor layer above the semiconductor layer.

8. The method for producing a plurality of semiconductor laser chips according to claim 1, wherein the semiconductor laser chips are connected with the auxiliary carrier exclusively via the support regions at the start of transferring.

9. A semiconductor laser chip comprising:
a semiconductor layer,
a first mirror, and
a second mirror, wherein
the semiconductor layer comprises a first region and a second region,
the semiconductor layer comprises an active region, which is arranged in the second region,
the active region is arranged between the first mirror and the second mirror, wherein the first mirror and the second mirror are adjacent to the second region, and
the second region is arranged on the first region along a vertical direction, which runs perpendicular to the main extension plane of the semiconductor layer.

10. The semiconductor laser chip according to claim 9, wherein the first region and the second region comprise different extensions from each other parallel to the main extension plane of the semiconductor layer.

11. The semiconductor laser chip according to claim 9, wherein an encapsulation is arranged at the side of the first mirror facing away from the second region.

12. The semiconductor laser chip according to claim 9, wherein the first mirror is free of an encapsulation.

13. The semiconductor laser chip according to claim 9, wherein the first region comprises a larger extension parallel to the main extension plane of the semiconductor layer than the second region.

14. The semiconductor laser chip according to claim 13, wherein the first mirror and the second mirror each comprise a main extension plane, which runs perpendicular to the main extension plane of the semiconductor layer, and wherein the first mirror comprises a lower reflectivity than the second mirror.

15. The semiconductor laser chip according to claim 9, wherein the semiconductor layer comprises two side edges, which extend transversely to the main extension plane of the semiconductor layer.

16. The semiconductor laser chip according to claim 9, wherein the semiconductor laser chip comprises a third mirror and a fourth mirror, which are both arranged on the side of the semiconductor layer where the semiconductor layer comprises the largest extension parallel to its main extension plane, wherein the third mirror and the fourth mirror each comprise a main extension plane which is parallel to the main extension plane of the semiconductor layer.

17. The semiconductor laser chip according to claim 16, wherein the third mirror comprises a lower reflectivity than the fourth mirror and the first region comprises a larger extension parallel to the main extension plane of the semiconductor layer than the second region.

18. The semiconductor laser chip according to claim 16, wherein the first mirror and the second mirror each comprise a main extension plane, which extends transversely to the main extension plane of the semiconductor layer, the third mirror comprises a lower reflectivity than the fourth mirror, and the first region comprises a smaller extension parallel to the main extension plane of the semiconductor layer than the second region.

19. The semiconductor laser chip according to claim 9, wherein the first region comprises a larger extension parallel to the semiconductor layer than the second region, in the first region the side edges of the semiconductor layer extend perpendicular to the main extension plane of the semiconductor layer, and in the second region, the side edges of the semiconductor layer extend transversely to the main extension plane of the semiconductor layer.

20. A semiconductor laser chip system comprising:
at least one semiconductor laser chip according to claim 9, and
at least one waveguide, wherein
a radiation exit surface of the semiconductor laser chip is optically connected to the waveguide.
